(19) United States
(12) Patent Application Publication
(10) Pub. No.: US 2024/0243113 A1
(43) Pub. Date: Jul. 18, 2024

(54) THIN SYSTEM-IN-PACKAGE WITH SHIELDED STEPPED MOLD

(71) Applicant: Apple Inc., Cupertino, CA (US)

(72) Inventor: Sidharth S. Dalmia, San Jose, CA (US)

(21) Appl. No.: 18/096,174

(22) Filed: Jan. 12, 2023

(51) Int. Cl. H01L 25/16; H01L 23/00; H01L 23/31; H01L 23/498; H01L 23/538; H01L 23/552

(52) U.S. Cl. CPC H01L 25/165; H01L 23/3121; H01L 23/49811; H01L 23/49822; H01L 23/49833; H01L 23/5385; H01L 23/552; H01L 24/16; H01L 2224/16225

(57) ABSTRACT

A system-in-package for an electronic device with a reduced thickness is presented herein. The system-in-package includes a stepped mold, an insulation film substrate, at least one processor die, and at least one passive element. The insulation film substrate is connected to a multi-layer board via a first plurality of connectors. The at least one processor die is integrated into the stepped mold and stacked onto the insulation film substrate via a second plurality of connectors. The at least one passive element is integrated into the stepped mold and stacked onto the insulation film substrate.

### BACKGROUND

### 1. Field of the Disclosure

The present disclosure relates to packaging technology, and more specifically to a thin system-in-package with a shielded stepped mold.

### 2. Description of the Related Arts

Generally, radio frequency devices may include a package, such as a system in package. A system-in-package incorporates substrates, dies, multiple integrated circuits, and/or passive devices into a single package. The system-in-package may be made of semiconducting material, such as silicon. For example, the substrates and dies may include silicon on which the integrated circuits are fabricated. The substrates, dies, and devices may be coupled by wires bonded to the package or by solder joints (e.g., solder balls or pads). By way of example, the dies may be stacked (e.g., two-and-a-half-dimensional (2.5D) or three-dimensional (3D) stack structure) to combine the dies into the same package rather than placing them on a printed circuit board. In some instances, the system-in-package may also include multiple packages that are stacked (e.g., using a package on package technique) or have dies embedded in a substrate.

By way of example, radio frequency devices that support communication over millimeter wave (mmWave) range frequencies often provide support at frequencies at or near 30 GHz. In some instances, radio frequency devices may also support the mm Wave communication over additional mmWave bands for broader frequency coverage, such as for 30-300 GHz. Multiple antennas (e.g., an antenna array) of the radio frequency devices may send signals that are combined to form a beam (e.g., a beamformed signal) for communication over the mmWave. To enable consistent coverage (e.g., from base stations associated with the mmWave communications), the radio frequency devices may include multiple antenna arrays positioned in different parts of the radio frequency devices. However, fitting these multiple antenna arrays in the system-in-package of the radio frequency devices may take up space and undesirably increase the size of the radio frequency devices.

### SUMMARY

Embodiments of the present disclosure relate to a first system-in-package for an electronic device with a reduced thickness. The first system-in-package includes a stepped mold, an insulation film substrate connected to a multi-layer board via a first plurality of connectors, at least one processor die integrated into the stepped mold and stacked onto the insulation film substrate via a second plurality of connectors, and at least one passive element integrated into the stepped mold and stacked onto the insulation film substrate.

Embodiments of the present disclosure are further directed to a second system-in-package for an electronic device with a reduced thickness. The second system-in-package includes a stepped mold, an insulation film substrate connected to a multi-layer board via a first plurality of connectors, at least one processor die and at least one of a radio frequency front-end die and a power control die integrated into the stepped mold and stacked onto the insulation film substrate via a second plurality of connectors, and a plurality of passive elements of different heights integrated into the stepped mold and stacked onto the insulation film substrate.

Embodiments of the present disclosure are further directed to a third system-in-package for an electronic device with a reduced thickness. The third system-in-package includes a stepped mold, a multi-layer board, an insulation film substrate connected to the multi-layer board via a first plurality of connectors, at least one processor die integrated into the stepped mold and stacked onto the insulation film substrate via a second plurality of connectors, and a plurality of passive elements integrated into the stepped mold and stacked onto the insulation film substrate, one of the plurality of passive elements is staked onto the insulation film substrate via a third plurality of connectors placed within a recess of the insulation film substrate.

### BRIEF DESCRIPTION OF THE DRAWINGS

Figure (FIG. 1A is a high-level diagram of an electronic device, according to one embodiment.

FIG. 1B is a perspective view of a notebook computer representing an embodiment of the electronic device of FIG. 1A.

FIG. 1C is a front view of a handheld device representing another embodiment of the electronic device of FIG. 1A, according to one embodiment.

FIG. 1D is a front view of another handheld device representing another embodiment of the electronic device of FIG. 1A, according to one embodiment.

FIG. 1E is a front view of a desktop computer representing another embodiment of the electronic device of FIG. 1A, according to one embodiment.

FIG. 1F is a front view and side view of a wearable electronic device representing another embodiment of the electronic device of FIG. 1A, according to one embodiment.

FIG. 2 is a schematic diagram of a system package of the electronic device of FIG. 1A, according to one embodiment.

FIG. 3 is a schematic diagram of a first system-in-package, according to one embodiment.

FIG. 4 is a schematic diagram of a second system-in-package, according to one embodiment.

FIG. 5 is a schematic diagram of a third system-in-package, according to one embodiment.

FIG. 6 is a schematic diagram of a fourth system-in-package, according to one embodiment.

FIG. 7 is a schematic diagram of a fifth system-in-package, according to one embodiment.

FIG. 8 is a schematic diagram of a sixth system-in-package, according to one embodiment.

The figures depict, and the detail description describes, various non-limiting embodiments for purposes of illustration only.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, the described embodiments may be practiced without these specific details. In other instances, well-known methods, procedures, components, circuits, and networks have not been described in detail so as not to unnecessarily obscure aspects of the embodiments.

Embodiments of the present disclosure relate to a system-in-package for an electronic device with components integrated into a stepped mold for a thickness reduction. The system-in-package may include a stepped mold having multiple (e.g., stepped) thicknesses for integrating components of different heights (or thicknesses). The system-in-package may further include an insulation film substrate that is placed onto a multi-layer board via connectors. The multi-layer board may be an external to the system-in-package. At least one processor die and optionally at least one radio frequency front-end die may be integrated into the stepped mold and stacked onto the insulation film substrate via connectors. Multiple tunable passive elements of different heights (or thicknesses) may be integrated into the stepped mold and staked onto the insulation film substrate. At least one of the passive elements can be connected to the insulation film substrate via connectors placed within a recess of the insulation film substrate. One of the passive elements may be placed within a recess of the stepped mold and directly connected to multi-layer board via connectors. The stepped mold may be covered by a shielding film, which may be an outer layer of the system-in-package. An electro-magnetic interference (EMI) absorber may be placed above a portion of the shielding film. Alternatively or additionally, the EMI absorber may be placed below the portion of the shielding film.

### Exemplary Electronic Device

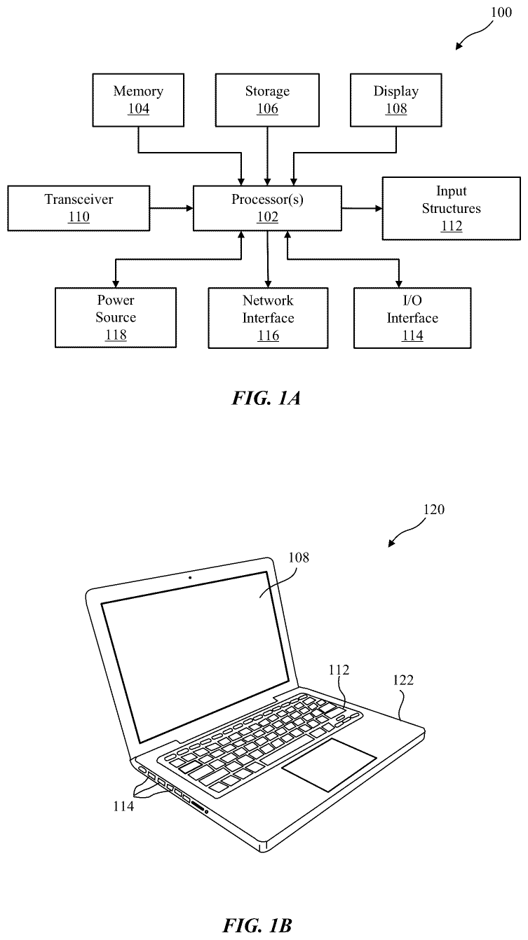

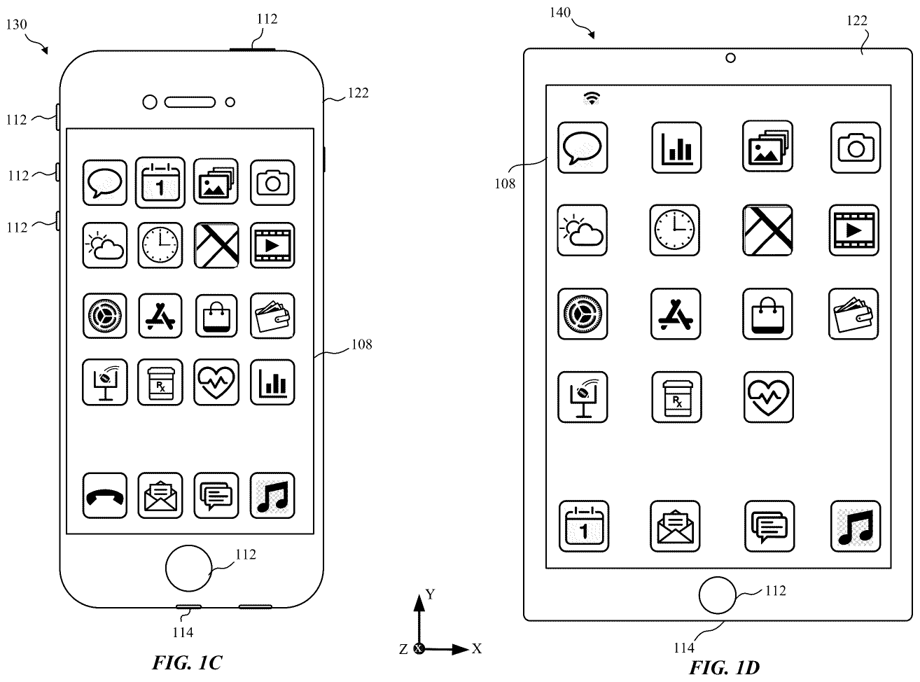

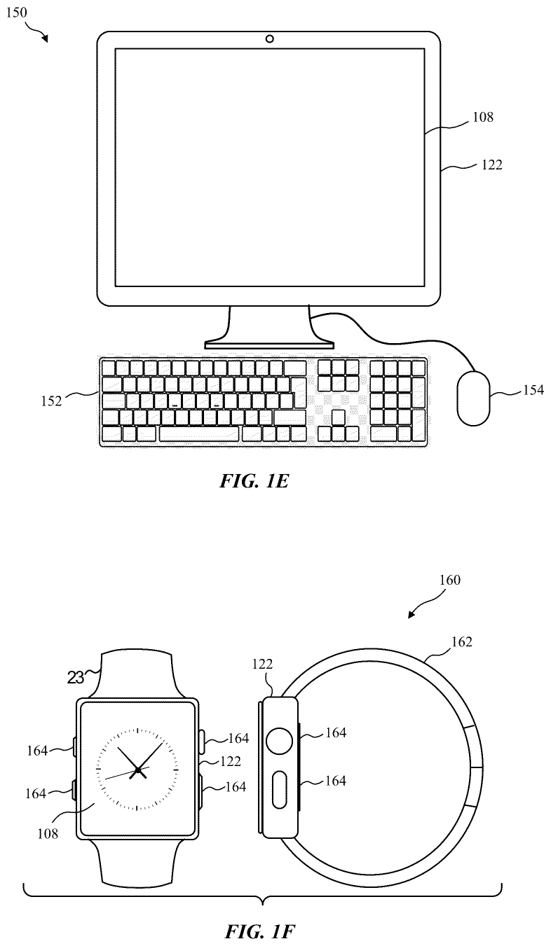

Embodiments of electronic devices, user interfaces for such devices, and associated processes for using such devices are described. In some embodiments, the device is a portable communications device, such as a mobile telephone, that also contains other functions, such as personal digital assistant (PDA) and/or music player functions. Exemplary embodiments of portable multifunction devices include, without limitation, the iPhone®, iPod Touch®, Apple Watch®, and iPad® devices from Apple Inc. of Cupertino, California. Other portable electronic devices, such as wearables, laptops or tablet computers, are optionally used. In some embodiments, the device is not a portable communication device, but is a desktop computer or other computing device that is not designed for portable use. In some embodiments, the disclosed electronic device may include a touch-sensitive surface (e.g., a touch screen display and/or a touchpad). An example electronic device described below in conjunction with Figure (FIG. 1 (e.g., an electronic device 100) may include a touch-sensitive surface for receiving user input. The electronic device may also include one or more other physical user-interface devices, such as a physical keyboard, a mouse and/or a joystick.

Figure (FIG. 1A is a high-level diagram of electronic device 100, according to one embodiment. Electronic device 100 may include, among other components, one or more processor(s) 102, a memory 104, a nonvolatile storage 106, a display 108, input structures 112, an input/output (I/O) interface 114, a network interface 116, a power source 118, and a transceiver 110. The various functional blocks shown in FIG. 1A may include hardware elements (including circuitry), software elements (including computer code stored on a computer-readable medium) or a combination of both hardware and software elements. It should be noted that FIG. 1A is merely one example of a particular implementation and is intended to illustrate the types of components that may be present in electronic device 100.

By way of example, electronic device 100 may represent a block diagram of a notebook computer depicted in FIG. 1B, handheld device depicted in FIG. 1C, handheld device depicted in FIG. 1D, desktop computer depicted in FIG. 1E, wearable electronic device depicted in FIG. 1F, or similar devices. It should be noted that processor(s) 102 and other related items in FIG. 1A may be generally referred to herein as “data processing circuitry.” Such data processing circuitry may be embodied wholly or in part as software, hardware, or any combination thereof. Furthermore, processor(s) 102 and other related items in FIG. 1A may be a single contained processing module or may be incorporated wholly or partially within any of the other elements within electronic device 100.

In electronic device 100 of FIG. 1A, processor(s) 102 may be operably coupled with memory 104 and nonvolatile storage 106 to perform various algorithms. For example, algorithms for adjusting input/output power of antennas may be saved in memory 104 and/or nonvolatile storage 106. Such algorithms or instructions executed by processor(s) 102 may be stored in any suitable article of manufacture that includes one or more tangible, computer-readable media. Moreover, antenna gain lookup tables used for determining total transmission gains and/or total reception gains may be saved in memory 104 and/or nonvolatile storage 106. Specifically, one or more codebooks may be stored in memory 104 and/or nonvolatile storage 106. The tangible, computer-readable media may include memory 104 and/or nonvolatile storage 106, individually or collectively, to store the algorithms or instructions. Memory 104 and nonvolatile storage 106 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by processor(s) 102 to enable electronic device 100 to provide various functionalities.

In certain embodiments, display 108 may be a liquid crystal display (LCD), which may facilitate users to view images generated on electronic device 100. In some embodiments, display 108 may include a touch screen, which may facilitate user interaction with a user interface of electronic device 100. Furthermore, it should be appreciated that, in some embodiments, display 108 may include one or more light-emitting diode (LED) displays, organic light-emitting diode (OLED) displays, active-matrix organic light-emitting diode (AMOLED) displays, or some combination of these and/or other display technologies.

Input structures 112 of electronic device 100 may enable a user to interact with electronic device 100 (e.g., pressing a button to increase or decrease a volume level). I/O interface 114 may enable electronic device 100 to interface with various other electronic devices, as may network interface 116. Network interface 116 may include, for example, one or more interfaces for a personal area network (PAN), such as a BLUETOOTH® network, for a local area network (LAN) or wireless local area network (WLAN), such as an 802.11x WI-FI® network, and/or for a wide area network (WAN), such as a 3^{rd} generation (3G) cellular network, universal mobile telecommunication system (UMTS), 4^{th} generation (4G) cellular network, long term evolution (LTE®) cellular network, long term evolution license assisted access (LTE-LAA) cellular network, 5^{th} generation (5G) cellular network, and/or New Radio (NR) cellular network. In particular, network interface 116 may include, for example, one or more interfaces for using a Release-15 cellular communication standard of the 5G specifications that include the millimeter wave (mmWave) frequency range (e.g., 30-300 GHz). Transceiver 110 of electronic device 100, which includes a transmitter and receiver, may allow communication over the aforementioned networks (e.g., 5G, Wi-Fi, LTE-LAA, etc.).

Network interface 116 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, etc.

In some embodiments, electronic device 100 communicates over the aforementioned wireless networks (e.g., WI-FI®, WIMAX®, mobile WIMAX®, 4G, LTER, 5G, etc.) using transceiver 110. Transceiver 110 may include circuitry useful in both wirelessly receiving the reception signals at the receiver and wirelessly transmitting the transmission signals from the transmitter (e.g., data signals, wireless data signals, wireless carrier signals, radio frequency signals). In some embodiments, transceiver 110 may include the transmitter and the receiver combined into a single unit, or, in other embodiments, transceiver 110 may include the transmitter separate from the receiver. Transceiver 110 may transmit and receive radio frequency signals to support voice and/or data communication in wireless applications such as, for example, PAN networks (e.g., BLUETOOTH®), WLAN networks (e.g., 802.11x WI-FI®), WAN networks (e.g., 3G, 4G, 5G, NR, and LTE® and LTE-LAA cellular networks), WIMAX® networks, mobile WIMAX® networks, ADSL and VDSL networks, DVB-T® and DVB-H® networks, UWB networks, etc. As further illustrated, electronic device 100 may include power source 118. Power source 118 may include any suitable source of power, such as a rechargeable lithium polymer (Li-poly) battery and/or an alternating current (AC) power converter.

In certain embodiments, electronic device 100 may take the form of a computer, a portable electronic device, a wearable electronic device, or other type of electronic device. Such computers may be generally portable (such as laptop, notebook, and tablet computers), or generally used in one place (such as desktop computers, workstations, and/or servers). In certain embodiments, electronic device 100 in the form of a computer may be a model of a MacBook®, MacBook® Pro, MacBook Air®, iMac®, Mac® mini, or Mac Pro® available from Apple Inc. of Cupertino, California. By way of example, electronic device 100, taking the form of a notebook computer 120, is illustrated in FIG. 1B in accordance with one embodiment of the present disclosure. Notebook computer 120 may include a housing or enclosure 122, a display 108, input structures 112, and ports of an I/O interface 114. In one embodiment, input structures 112 (such as a keyboard and/or touchpad) may be used to interact with computer 120, such as to start, control, or operate a graphical user interface (GUI) and/or applications running on computer 120. For example, a keyboard and/or touchpad may allow a user to navigate a user interface and/or an application interface displayed on display 108.

FIG. 1C depicts a front view of a handheld device 130, which represents one embodiment of electronic device 100. Handheld device 130 may represent, for example, a portable phone, a media player, a personal data organizer, a handheld game platform, or any combination of such devices. By way of example, handheld device 130 may be a model of an iPhone® available from Apple Inc. of Cupertino, California. Handheld device 130 may include an enclosure 122 to protect interior components from physical damage and/or to shield them from electromagnetic interference. Enclosure 122 may surround display 108. I/O interfaces 114 may open through enclosure 122 and may include, for example, an I/O port for a hardwired connection for charging and/or content manipulation using a standard connector and protocol, such as the Lightning connector provided by Apple Inc. of Cupertino, California, a universal serial bus (USB), or other similar connector and protocol. Interfaces 114 may be associated with wiring and connectors within the radio frequency packaging of electronic device 100. The wiring and connectors may result in particular areas within a system package of electronic device 100 that are available for placing components to facilitate supporting multiple wireless communication protocols and capabilities. By way of example, if handheld device 130 is positioned upward along a positive portion of z-axis and facing a positive portion of y-axis, an antenna array of a right side panel of handheld device 130 may be disposed and radiate signals in a positive portion of x-axis. Similarly, an antenna array of a left side panel may be disposed and radiate signals in a negative portion of x-axis, an antenna array of a front glass panel (e.g., front surface panel) may be disposed and radiate signals in the positive portion of y-axis, and an antenna array of a back glass panel (e.g., rear surface panel) may be disposed and radiate signals in a negative portion of y-axis.

Input structures 112, in combination with display 108, may allow a user to control handheld device 130. For example, input structures 112 may activate or deactivate handheld device 130, navigate user interface to a home screen, a user-configurable application screen, and/or activate a voice-recognition feature of handheld device 130. Other input structures 112 may provide volume control, or may toggle between vibrate and ring modes. Input structures 112 may also include a microphone that may obtain a user's voice for various voice-related features, and a speaker that may enable audio playback and/or certain phone capabilities. Input structures 112 may also include a headphone input that may provide a connection to external speakers and/or headphones.

FIG. 1D depicts a front view of another handheld device 140, which represents another embodiment of electronic device 100. Handheld device 140 may represent, for example, a tablet computer, or one of various portable computing devices. By way of example, handheld device 140 may be a tablet-sized embodiment of electronic device 100, which may be, for example, a model of an iPad® available from Apple Inc. of Cupertino, California.

Turning to FIG. 1E, a computer 150 may represent another embodiment of electronic device 100 of FIG. 1A. Computer 150 may be any computer, such as a desktop computer, a server, or a notebook computer, but may also be a standalone media player or video gaming machine. By way of example, computer 150 may be an iMac®, a MacBook®, or other similar device by Apple Inc. of Cupertino, California. It should be noted that computer 150 may also represent a personal computer (PC) by another manufacturer. A similar enclosure 122 may be provided to protect and enclose internal components of computer 150, such as display 108. In certain embodiments, a user of computer 150 may interact with computer 150 using various peripheral input structures 112, such as a keyboard 152 or a mouse 154 (e.g., input structures 112), which may connect to computer 150.

Similarly, FIG. 1F depicts a wearable electronic device 160 representing another embodiment of electronic device 100 that may be configured to operate using the techniques described herein. By way of example, wearable electronic device 160, which may include a wristband 162, may be an Apple Watch® by Apple Inc. of Cupertino, California. However, in other embodiments, wearable electronic device 160 may include any wearable electronic device such as, for example, a wearable exercise monitoring device (e.g., pedometer, accelerometer, heart rate monitor), or other device by another manufacturer. Display 108 of wearable electronic device 160 that is surrounded by enclosure 122 may include a touch screen display 108 (e.g., LCD, LED display, OLED display, AMOLED display, etc.), as well as input structures 112, which may allow users to interact with a user interface of wearable electronic device 160.

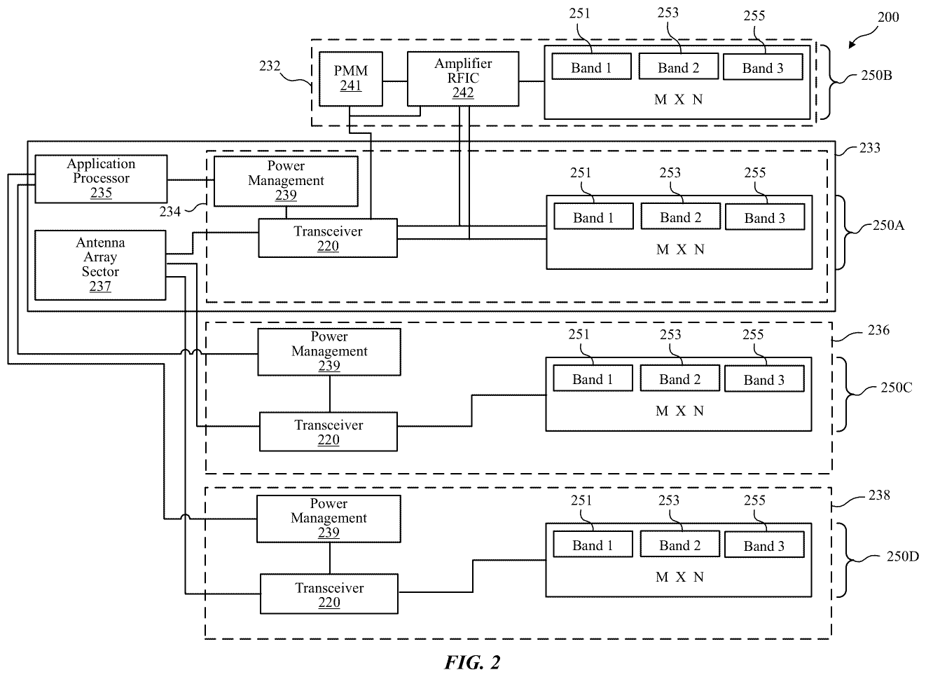

FIG. 2 is a schematic diagram of a system-in-package 200 of electronic device 100 of FIG. 1A. Although the depicted embodiment shows multiple panels on different sides and on the same layer of electronic device 100, the systems described herein also apply to stacked panels, such as a three-dimensional (3D) stack of printed circuit boards. That is, one or more of the panels may be positioned on top of or beneath one or more other panels. Moreover, at least one of the panels may include a redistribution printed circuit board that provides a connection between the panels that are coupled to the redistribution printed circuit board.

In the depicted embodiment, system-in-package 200 includes packaging for a front glass panel 232 (e.g., front surface panel or cover glass panel), a main logic board 233 with a back glass panel 234, a left side panel 236, and a right side panel 238. Although the following descriptions describe panels 232, 234, 236, and 238 as disposed respectively on the front, back, left, and right side of electronic device 100, which represents a particular embodiment, system-in-package 200 described herein may additionally or alternatively include panel(s) disposed at other areas of electronic device 100 that may include one or more antennas. For example, system-in-package 200 may also include top side or bottom side panels disposed respectively at the top or bottom of electronic device 100, adjacent to left side panel 236 and right side panel 238. Moreover, although the following descriptions describe an antenna array, which represents a particular embodiment, system-in-package 200 described herein may additionally or alternatively include multiple antenna arrays.

Main logic board 233 may include back glass panel 234, a power management circuit 239, transceiver 220, an antenna array selector 237, an application processor 235, and a first antenna array 250A. Application processor 235 may be coupled to power management circuit 239 to control power functions, including those related to wireless communications. Power management circuit 239 may include one or more integrated circuits and control power (e.g., via processor 102) provided to components of main logic board 233 and/or electronic device 100, including, for example, transceiver 220 and/or antenna array selector 237. By way of example, power management circuit 239 may control supplying power to main logic board 233, providing power to components on or coupled to main logic board 233, panels 232, 234, 236, and/or 238, selecting a power source, power sequencing, converting direct current (DC) for specific power related functions, charging a battery of electronic device 100, etc.

As shown, transceiver 220 may be coupled to antenna array selector 237, first antenna array 250A of back glass panel 234, and components of front glass panel 232. Antenna array 250A includes multiple antennas that transmit and/or receive wireless signals, and that may form a directional beam using signals emitted by each of the antennas. Transceiver 220 may be an embodiment of transceiver 110. Transceiver 110, as previously discussed with respect to FIG. 1A, is a device that includes a transmitter and a receiver in a single package, and may transmit and receive data via wireless signals communicated on particular radio frequency using the antennas of first antenna array 250A. Specifically, transceiver 220 may include a transmitter and a receiver that include components that facilitate transmission and reception of wireless signals, such as those sent and received between electronic devices 100 using mmWave communication technology or any other suitable communication protocol. When communicating on the mmWave frequencies, electronic device 100 may utilize beamforming techniques to form the directional beam, as previously mentioned. The transmitter of transceiver 220 may include one or more phase shifters, transmitter power detectors, and power amplifiers. The transmitter phase shifters may modulate (e.g., phase-shift) transmission signals (e.g., wireless signals transmitted from antennas of first antenna array 250A) and may form a beam that may be steered in a particular direction (e.g., the directional beam), such as towards another electronic device (e.g., another electronic device 100, or a base station). The power amplifiers may amplify power level of transmission signals. Specifically, the power amplifiers may be supplied with a power amplifier supply voltage to control the amount of amplification provided by the power amplifiers (e.g., increase or decrease amplification, which may affect the antenna gain at the corresponding antennas). The transmitter power detectors may measure power of the transmission signals sent from the antennas of first antenna array 250A.

The receiver of transceiver 220 may include one or more receiver phase shifters, low noise amplifiers, and receiver power detectors. The receiver phase shifters and the receiver power detectors may function similarly to the transmitter phase shifters and the transmitter power detectors. The low noise amplifiers may amplify the power level of reception signals (e.g., wireless signals received at antennas of first antenna array 250A). Additional components in the transmitter and/or the receiver may include, but are not limited to, filters, mixers, and/or attenuators.

Antenna array selector 237, which may be coupled to transceiver 220, may activate or enable communication from one or more of the antennas of antenna arrays 250, such as first antenna array 250A. For example, based on data throughput, antenna array selector 237 may selectively enable a number of antennas to accommodate the data throughput. As shown, first antenna array 250A is disposed at back glass panel 234. Back glass panel 234 may include one or more printed circuit boards that are coupled to a rear surface (e.g., a back glass) of electronic device 100. As shown, first antenna array 250A may include an M×N array of first band antennas 251 (Band 1), second band antennas 253 (Band 2), and third band antennas 255 (Band 3). The M×N array may refer to M rows (e.g., one or more rows) and N columns (e.g., one or more columns) of antennas in which the number of rows, column, and/or antennas in the rows and columns may include any number antennas suitable for the particular application (e.g., communications over the mmWave). Additionally, although the following descriptions describe antenna arrays 250 with a particular number of first band antennas 251, second band antennas 253, and third band antennas 255, which represent particular embodiments, antenna arrays 250 may include one or more of any of first band antennas 251, second band antennas 253, and/or third band antennas 255. First band antennas 251 may enable communication in a first band or range of frequencies, second band antennas 253 may enable communication in a second band or range of frequencies, and third band antennas 255 may enable communication in a third band or range of frequencies. In some embodiments, the first band, the second band, and the third band may include different ranges of frequencies. By way of example, the first band may include low-band frequencies, such as 700 MHz to 1.0 GHz, second band antennas 253 may enable communication in mid-band frequencies, such as 1.8 GHz to 2.2 GHZ, and third band antennas 255 may enable communication in high-band frequencies, such as 20 GHz to 80 GHz.

Additionally, transceiver 220 may be coupled to a power management module (PMM) 241 and an amplifier radio frequency integrated circuit (RFIC) 242 of front glass panel 232. Power management module 241 may provide power for the power amplifier of transceiver 220 to amplify power for the transmission signals. Amplifier RFIC 242 may provide mixing circuitry to demodulate radio frequency signals received by transceiver 220 and modulate intermediate frequency signals to radio frequency signals for transmitting transmission signals from transceiver 220.

In some embodiments, application processor 235 may control antenna array selector 237 and/or transceivers 220 (e.g., through antenna array selector 237), and by extension, antenna arrays 250 of front glass panel 232, back glass panel 234, left side panel 236, and/or right side panel 238. That is, antenna array selector 237 may enable one or more of the antennas of one or more antenna arrays 250 (e.g., antenna arrays 250A, 250B, 250C, 250D) to transmit or receive wireless signals via transceivers 220. In some embodiments, antenna array selector 237 may enable antennas of right side panel 238 to transmit signals contributing to a beamformed signal directed to the right with respect to electronic device 100. By way of example, if electronic device 130 of FIG. 1C is positioned upward in a positive portion of z-axis and facing a positive portion of y-axis, right side panel 238 may be disposed and radiate signals in a positive portion of x-axis. Application processor 235 may also be communicatively coupled to power management circuits 239 of each of front glass panel 232, main logic board 233, back glass panel 234, left side panel 236, and right side panel 238 to control power related functions with respect to each of the panels.

Application processor 235 may include one or more microprocessors, one or more “general-purpose” microprocessors, one or more special-purpose microprocessors, and/or one or more application specific integrated circuits (ASICs), or some combination thereof. For example, application processor 235 may include one or more reduced instruction set (RISC) processors. In some instances, application processor 235 may perform processing (e.g., execute software programs and/or instructions) for specific functions, such as specific wireless communication related functions. The specific functions may include receiving or generating wireless signals, selecting particular antennas for transmitting or receiving signals using antenna array selector 237, selecting an amplification level to amplify transmission signals using power management circuit 239, determining gain of the wireless signals transmitted and/or received from a particular transmitter and/or receiver associated with a particular antenna of antenna array 250, etc. In some instances, application processor 235 may be integrated with processor(s) 102 and perform additional functions related to the wireless communications, such as functions related to display 108, adjusting bandwidth consumption, and so on.

In some embodiments, application processor 235 may communicate with one or more memory devices (not shown in FIG. 2), such as memory 104 of FIG. 1A, for processing instructions to perform the functions related to wireless communications. The memory device may store information such as control software, configuration data, etc. In some embodiments, application processor 235 and the memory device may be external to main logic board 233 and/or system package 230. The memory device may include a tangible, non-transitory, machine-readable-medium, such as a volatile memory (e.g., a random access memory (RAM)) and/or a nonvolatile memory (e.g., a read-only memory (ROM)). The memory device may store a variety of information and may be used for various purposes. For example, the memory device may store machine-readable and/or processor-executable instructions (e.g., in the form of software or a computer program) for application processor 235 to execute, such as instructions for enabling communication from a particular antenna transmitting or receiving signals contributing to a beamformed signal transmitted or received in a particular beam direction at a particular frequency. The memory device may include one or more storage devices (e.g., nonvolatile storage devices) that may include ROM, flash memory, a hard drive, or any other suitable optical, magnetic, or solid-state storage medium, or a combination thereof.

As shown, system package 230 also includes front glass panel 232, which may include one or more printed circuit boards that are coupled to a cover glass associated with display 108. Front glass panel 232 may include a second antenna array 250B having M×N first band antennas 251, M×N second band antennas 253, and/or M×N third band antennas 255. The antennas of second antenna array 250B function similarly to the antennas of first antenna array 250A of main logic board 233. That is, by way of example, first band antennas 251 may communicate wireless signals on low-bands frequencies (e.g., 700 MHz to 1.0 GHz), second band antennas 253 may communicate wireless signals on mid-band frequencies (e.g., 1.8 GHz to 2.2 GHZ), and third band antennas 255 may communicate wireless signals on high-band frequencies (e.g., 20 GHz to 80 GHz).

Front glass panel 232 may also include amplifier RFIC 242 (e.g., a low noise amplifier (LNA) and power amplifier (PA) radio frequency integrated circuit (RFIC)) and power management module 241. Amplifier RFIC 242 may include circuitry between antennas and mixing circuitry that, for example, process a signal at an incoming radio frequency (RF) before the signal is converted or demodulated to a lower intermediate frequency (IF) for processing (e.g., converting from RF to IF). By way of example, amplifier RFIC 242 may include a processor 102 that processes instructions for functions performed by amplifier RFIC 242 (e.g., instructions related to frequency conversion, transmitting signals from particular antennas and having particular amplification, receiving signals at particular antennas, etc.) and/or a memory 104 storing the instructions related to functions performed by amplifier RFIC 242. In some embodiments, amplifier RFIC 242 may include a band-pass filter to pass frequencies within a particular range and/or a stop-band filter to filter frequencies out the particular range, a low noise amplifier to increase a signal strength of an incoming signal, a local oscillator that generates a radio frequency signal at an offset from the incoming signal to be mixed with the incoming signal, and/or a mixer that mixes the incoming signal with a signal from the local oscillator to convert the incoming signal to the intermediate frequency. A power convertor (e.g., a direct current (DC)-to-DC convertor (DC-DC convertor)) of power management module 241 may supply power to the power amplifier of electronic device 100, for example, for amplifying a transmission signal. As such, dynamically changing the supply voltage from the power convertor may correspondingly change the amount of amplification to the transmission signal from the power amplifier. Furthermore, an average power tracking (APT) of power management module 241 may change the DC supply voltage based on an output power level to maintain linearity of the power amplifier while efficiency may be improved (e.g., reduce unnecessary power consumption by the power amplifier).

As illustrated, system-in-package 200 also includes left side panel 236, which may include one or more printed circuit boards that are connected to a left side of electronic device 100. Left side panel 236 may also include a power management circuit 239, transceiver 220, and third antenna array 250C. Similarly, system-in-package 200 includes a right side panel 238. Right side panel 238 may also include a power management circuit 239, transceiver 220, and fourth antenna array 250D. Power management circuits 239, transceivers 220, and antenna arrays 250C, 250D may operate and function similarly to power management circuit 239, transceiver 220, and first antenna array 250A, as discussed with respect to main logic board 233. As shown, third antenna array 250C and fourth antenna array 250D include M×N first band antennas 251, second band antennas 253, and third band antennas 255. As previously mentioned, by way of example, first band antennas 251 may communicate wireless signals on low-band frequencies, second band antennas 253 may communicate wireless signals on mid-band frequencies, and third band antennas 255 may communicate wireless signals on high-band frequencies.

As previously discussed, integrating the antennas of antenna arrays 250, transceivers 220, and power management circuits 239, within the same particular area within a package of the panels of system-in-package 200 may be difficult. Specifically, transceiver 220 and antenna array 250 may be co-located (e.g., near each other in the same or approximately the same area) in the package so that transceiver 220 may efficiently control amplification, phase, gain, etc., of the wireless signals while minimizing signal loss and noise that may otherwise result from longer communication pathways between transceiver 220 and antenna array 250 (e.g., not co-located). Similarly, power management circuit 239 may be co-located with transceiver 220 and antenna array 250 so that transceiver 220 may efficiently control power related functions for the wireless signals from the antennas of antenna array 250 while also minimizing signal loss and noise. Moreover, electronic device 100 may include additional antennas for higher data throughput via the antennas and/or to provide higher gain of the wireless signals from the antennas. In some embodiments, electronic device 100 includes additional components and/or additional antennas to accommodate a carrier aggregation that is unique to a particular wireless carrier. System-in-package 200 may efficiently accommodate the co-located components, the additional number of antennas, other components, and/or package specifications, while reducing occupying space (or maintain initial system-in-package 200 dimensions after adding additional components and antennas).

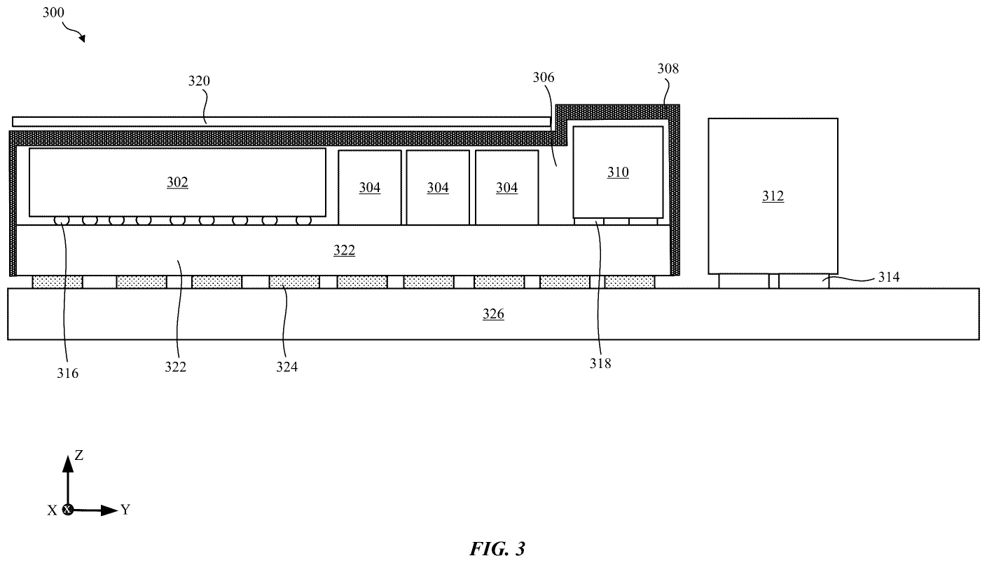

Although the following descriptions describe space reduction (e.g., thickness reduction) packaging techniques applied to a particular panel of system-in-package 200, the techniques may also apply to the other panels of system-in-package 200. By way of example, descriptions of the space reduction (e.g., thickness reduction) packaging techniques applied to front glass panel 232 may also apply to main logic board 233, back glass panel 234, left side panel 236, and/or right side panel 238. Details about various thickness reduction packaging techniques for integration of system-in-packages are provided in relation to FIGS. 3 through 8.

### Example System-In-Packages

FIG. 3 is a schematic diagram of a system-in-package 300 that may be integrated into electronic device 100, according to one embodiment. System-in-package 300 may be a system-in-package integrated into front glass panel 232, main logic board 233, back glass panel 234, left side panel 236, or right side panel 238. System-in-package 300 may include at least one processor die 302, first passive elements 304, a second passive element 310, a stepped mold 306, and an insulation film substrate 322.

Processor die 302 may be integrated into stepped mold 306 and stacked onto insulation film substrate 322 via connectors 316 (e.g., solder ball connectors). Processor die 302 may include at least one microprocessor, at least one “general-purpose” microprocessor, at least one special-purpose microprocessor, at least one ASIC, or some combination thereof. In some embodiments, processor die 302 may perform processing for specific functions, such as specific wireless communication related functions. Processor die 302 may be an embodiment of application processor 235.

Stepped mold 306 is a molded cavity that has portions of different heights (or thicknesses) along, e.g., z dimension. Stepped mold 306 may allow integration of components of system-in-package 300 of different thicknesses for reduction of an overall thickness of system-in-package 300. Stepped mold 306 may be further utilized for inclusion of at least one shielding layer into system-in-package 300. Additionally or alternatively, stepped mold 306 may be further utilized for inclusion of at least one thermal heat dissipating material into system-in-package 300. A thickness of stepped mold 306 may be, e.g., between 0.395 mm and 0.415 mm.

Insulation film substrate 322 may be connected to a multi-layer board 326 via connectors 324, e.g., bumps, microbumps, hybrid bonds, copper pillars, land grid array (LGA) connectors, or ball grid array (BGA) connectors. Insulation film substrate 322 may be an insulating build-up material. Alternatively, insulation film substrate 322 may be replaced with an interposer. Multi-layer board 326 may be external to system-in-package 300. Multi-layer board 326 may be replaced with a flexible board 326. Alternatively, multi-layer board 326 may be replaced with a board 326 having at least one embedded component. At least one additional passive element 312 (e.g., capacitor, inductor, resistor, voltage regulator, etc.) may be directly stacked onto multi-layer board 326 via connectors 314 (e.g., LGA connectors or BGA connectors).

Each of first passive elements 304 and second passive element 310 may be integrated into stepped mold 306. First passive elements 304 and second passive element 310 may be capacitors, inductors, resistors, voltage regulators, some other type of passive elements, or some combination thereof. First passive elements 304 and second passive element 410 may be of different heights (or thicknesses). First passive elements 304 may be directly stacked onto insulation film substrate 322. Second passive element 310 may be connected to insulation film substrate 322 via connectors 318 (e.g., LGA connectors or BGA connectors).

System-in-package 300 may further include a shielding layer 308 that covers stepped mold 306 as an outer layer of system-in-package 300. Shielding layer 308 may provide electrical shielding for components in system-in-package 300. A thickness of shielding layer 308 may be, e.g., between 7 μm and 15 μm. System-in-package 300 may further include an absorber layer 320 (e.g., EMI absorber) placed above at least a portion of an outer surface of shielding layer 308. Alternatively (not shown in FIG. 3), absorber layer 320 may be placed below a portion of an inner surface of shielding layer 308. A maximum thickness of system-in-package 300 may be, e.g., 0.697 mm.

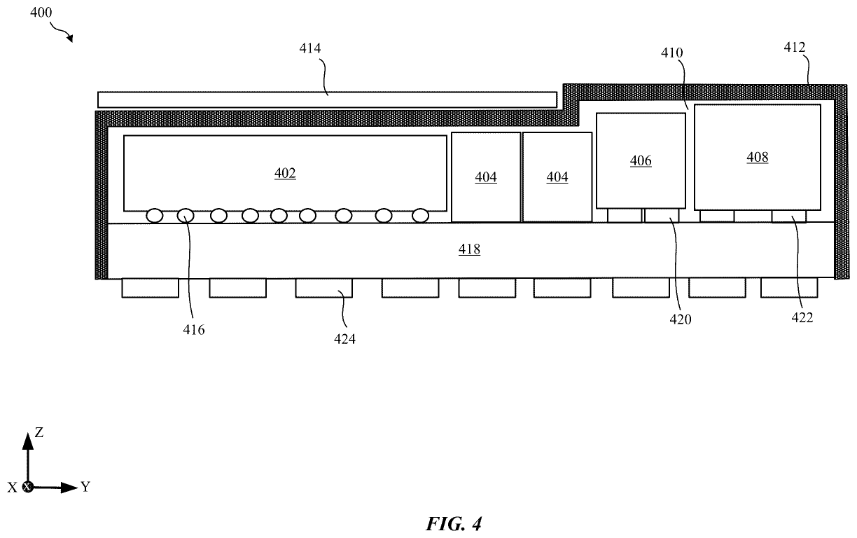

FIG. 4 is a schematic diagram of a system-in-package 400 that may be integrated into electronic device 100, according to one embodiment. System-in-package 400 may be a system-in-package integrated into front glass panel 232, main logic board 233, back glass panel 234, left side panel 236, or right side panel 238. System-in-package 400 may include at least one processor die 402, first passive elements 404, a second passive element 406, a third passive element 408, a stepped mold 410, and an insulation film substrate 418.

Processor die 402 may be integrated into stepped mold 410 and stacked onto insulation film substrate 418 via connectors 416 (e.g., solder ball connectors). Processor die 402 may include at least one microprocessor, at least one “general-purpose” microprocessor, at least one special-purpose microprocessor, at least one ASIC, or some combination thereof. In some embodiments, processor die 402 may perform processing for specific functions, such as specific wireless communication related functions. Processor die 402 may be an embodiment of application processor 235.

Stepped mold 410 is a molded cavity that has portions of different heights (or thicknesses) along, e.g., z dimension. Stepped mold 410 may allow integration of components of system-in-package 400 of different thicknesses for reduction of an overall thickness of system-in-package 400. Stepped mold 410 may be further utilized for inclusion of at least one shielding layer into system-in-package 400. Additionally or alternatively, stepped mold 410 may be further utilized for inclusion of at least one thermal heat dissipating material into system-in-package 400. A thickness of stepped mold 410 may be, e.g., between 0.57 mm and 0.59 mm.

Insulation film substrate 418 may be connected to a multi-layer board (not shown in FIG. 4) via connectors 424 (e.g., LGA connectors or BGA connectors). Insulation film substrate may be an insulating build-up material. Alternatively, insulation film substrate 418 may be replaced with an interposer. Each of first passive elements 404, second passive element 406 and third passive element 408 may be integrated into stepped mold 410. First passive elements 404, second passive element 406 and third passive element 408 may be capacitors, inductors, resistors, voltage regulators, some other type of passive elements, or some combination thereof. First passive elements 404, second passive element 406 and third passive element 408 may be of different heights (or thicknesses). Passive elements 404 may be directly stacked onto insulation film substrate 418. Second passive element 406 may be connected to insulation film substrate 418 via connectors 420 (e.g., LGA connectors or BGA connectors). Third passive element 408 may be connected to insulation film substrate 418 via connectors 422 (e.g., LGA connectors or BGA connectors).

System-in-package 400 may further include a shielding layer 412 that covers stepped mold 410 as an outer layer of system-in-package 400. Shielding layer 412 may provide electrical shielding for components in system-in-package 400. A thickness of shielding layer 412 may be, e.g., between 7 μm and 15 μm. System-in-package 400 may further include an absorber layer 414 (e.g., EMI absorber) placed above at least a portion of an outer surface of shielding layer 412. Alternatively (not shown in FIG. 4), absorber layer 414 may be placed below a portion of an inner surface of shielding layer 412. A maximum thickness of system-in-package 400 may be, e.g., 0.865 mm.

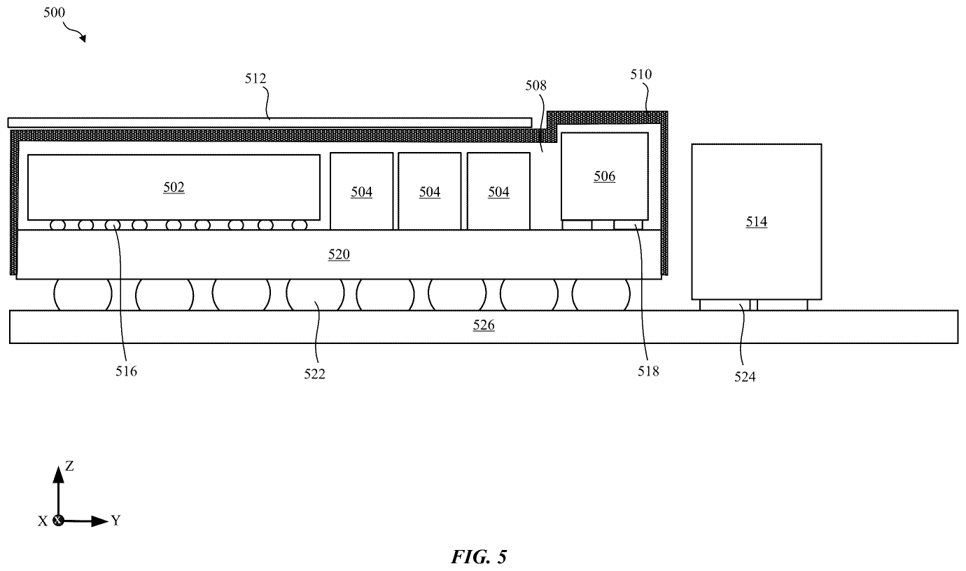

FIG. 5 is a schematic diagram of a system-in-package 500 that may be integrated into electronic device 100, according to one embodiment. System-in-package 500 may be a system-in-package integrated into front glass panel 232, main logic board 233, back glass panel 234, left side panel 236, or right side panel 238. System-in-package 500 may include at least one processor die 502, first passive elements 504, a second passive element 506, a stepped mold 508, and an insulation film substrate 510.

Processor die 502 may be integrated into stepped mold 508 and stacked onto insulation film substrate 520 via connectors 516 (e.g., solder ball connectors). Processor die 502 may include at least one microprocessor, at least one “general-purpose” microprocessor, at least one special-purpose microprocessor, at least one ASIC, or some combination thereof. In some embodiments, processor die 502 may perform processing for specific functions, such as specific wireless communication related functions. Processor die 502 may be an embodiment of application processor 235.

Stepped mold 508 is a molded cavity that has portions of different heights (or thicknesses) along, e.g., z dimension. Stepped mold 508 may allow integration of components of system-in-package 500 of different thicknesses for reduction of an overall thickness of system-in-package 500. Stepped mold 508 may be further utilized for inclusion of at least one shielding layer into system-in-package 500. Additionally or alternatively, stepped mold 508 may be further utilized for inclusion of at least one thermal heat dissipating material into system-in-package 500. A thickness of stepped mold 508 may be, e.g., between 0.395 mm and 0.415 mm.

Insulation film substrate 520 may be connected to a multi-layer board 526 via connectors 522 (e.g., solder ball connectors). Insulation film substrate 520 may be an insulating build-up material. Alternatively, insulation film substrate 520 may be replaced with an interposer. Multi-layer board 526 may be external to system-in-package 500. Multi-layer board 526 may be replaced with a flexible board 526. Alternatively, multi-layer board 526 may be replaced with a board 526 having at least one embedded component. At least one additional passive element 514 (e.g., capacitor, inductor, resistor, etc.) may be directly stacked onto multi-layer board 526 via connectors 524 (e.g., LGA connectors or BGA connectors).

Each of first passive elements 504 and second passive element 506 may be integrated into stepped mold 508. First passive elements 504 and second passive element 506 may be capacitors, inductors, resistors, voltage regulators, some other type of passive elements, or some combination thereof. First passive elements 504 and second passive element 506 may be of different heights (or thicknesses). First passive elements 504 may be directly stacked onto insulation film substrate 520. Second passive element 506 may be connected to insulation film substrate 520 via connectors 518 (e.g., LGA connectors or BGA connectors).

System-in-package 500 may further include a shielding layer 510 that covers stepped mold 508 as an outer layer of system-in-package 500. Shielding layer 510 may provide electrical shielding for components in system-in-package 500. A thickness of shielding layer 510 may be, e.g., between 7 μm and 15 μm. System-in-package 500 may further include an absorber layer 512 (e.g., EMI absorber) placed above at least a portion of an outer surface of shielding layer 510. Alternatively (not shown in FIG. 5), absorber layer 512 may be placed below a portion of an inner surface of shielding layer 510. A maximum thickness of system-in-package 500 may be, e.g., 0.752 mm.

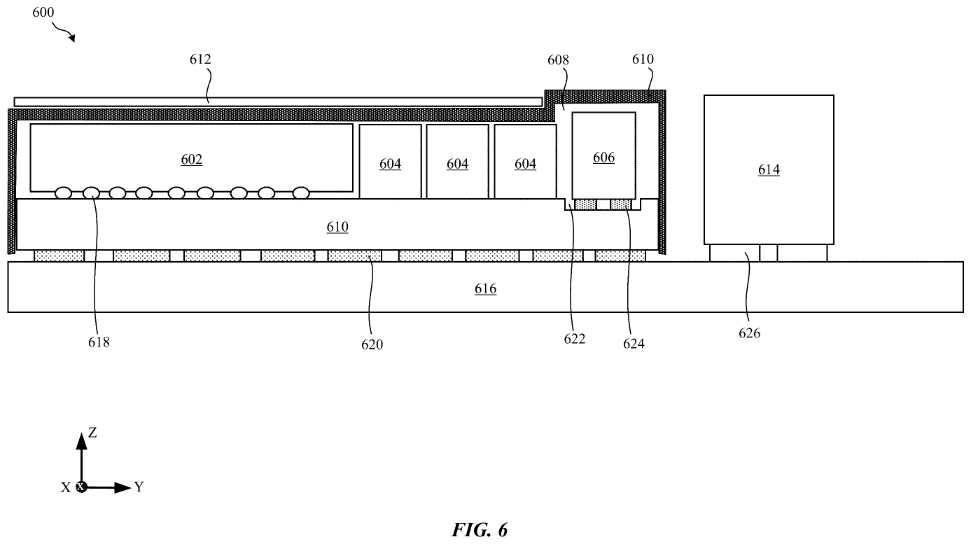

FIG. 6 is a schematic diagram of a system-in-package 60 that may be integrated into electronic device 100, according to one embodiment. System-in-package 600 may be a system-in-package integrated into front glass panel 232, main logic board 233, back glass panel 234, left side panel 236, or right side panel 238. System-in-package 600 may include at least one processor die 602, first passive elements 604, a second passive element 606, a stepped mold 608, and an insulation film substrate 610.

Processor die 602 may be integrated into stepped mold 608 and stacked onto insulation film substrate 610 via connectors 618 (e.g., solder ball connectors). Processor die 602 may include at least one microprocessor, at least one “general-purpose” microprocessor, at least one special-purpose microprocessor, at least one ASIC, or some combination thereof. In some embodiments, processor die 602 may perform processing for specific functions, such as specific wireless communication related functions. Processor die 602 may be an embodiment of application processor 235.

Stepped mold 608 is a molded cavity that has portions of different heights (or thicknesses) along, e.g., z dimension. Stepped mold 608 may allow integration of components of system-in-package 600 of different thicknesses for reduction of an overall thickness of system-in-package 600. Stepped mold 608 may be further utilized for inclusion of at least one shielding layer into system-in-package 600. Additionally or alternatively, stepped mold 608 may be further utilized for inclusion of at least one thermal heat dissipating material into system-in-package 600. A thickness of stepped mold 608 may be, e.g., between 0.35 mm and 0.37 mm.

Insulation film substrate 610 may be connected to a multi-layer board 616 via connectors 620 (e.g., LGA connectors or BGA connectors). Insulation film substrate 610 may be an insulating build-up material. Alternatively, insulation film substrate 610 may be replaced with an interposer. Multi-layer board 616 may be external to system-in-package 600. Alternatively, multi-layer board 616 may be an integral part of system-in-package 600. Multi-layer board 616 may be replaced with a flexible board 616. Alternatively, multi-layer board 616 may be replaced with a board 616 having at least one embedded component. At least one additional passive element 614 (e.g., capacitor, inductor, resistor, etc.) may be directly stacked onto multi-layer board 616 via connectors 626 (e.g., LGA connectors or BGA connectors).

Each of first passive elements 604 and second passive element 606 may be integrated into stepped mold 608. First passive elements 604 and second passive element 606 may be capacitors, inductors, resistors, voltage regulators, some other type of passive elements, or some combination thereof. First passive elements 604 and second passive element 606 may be of different heights (or thicknesses). First passive elements 604 may be directly stacked onto insulation film substrate 610. Second passive element 606 may be staked onto insulation film substrate 610 via connectors 624 (e.g., LGA connectors or BGA connectors) that are placed within a recess 622 of insulation film substrate 610. By placing connectors 624 within recess 622 of insulation film substrate 610, an overall thickness of system-in-package 600 can be further reduced (e.g., in comparison with system-in-packages 300, 400, and 500).

System-in-package 600 may further include a shielding layer 610 that covers stepped mold 608 as an outer layer of system-in-package 600. Shielding layer 610 may provide electrical shielding for components in system-in-package 600. A thickness of shielding layer 610 may be, e.g., between 7 μm and 15 μm. System-in-package 600 may further include an absorber layer 612 (e.g., EMI absorber) placed above at least a portion of an outer surface of shielding layer 610. Alternatively (not shown in FIG. 6), absorber layer 612 may be placed below a portion of an inner surface of shielding layer 610. A maximum thickness of system-in-package 600 may be, e.g., 0.692 mm.

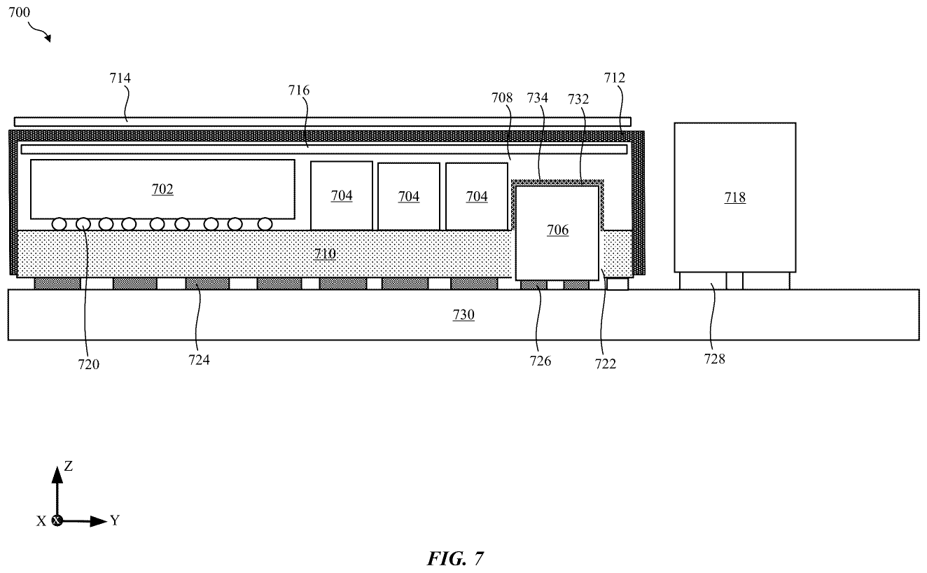

FIG. 7 is a schematic diagram of a system-in-package 700 that may be integrated into electronic device 100, according to one embodiment. System-in-package 700 may be a system-in-package integrated into front glass panel 232, main logic board 233, back glass panel 234, left side panel 236, or right side panel 238. System-in-package 700 may include at least one processor die 702, first passive elements 704, a second passive element 706, a stepped mold 708, and an insulation film substrate 710.

Processor die 702 may be integrated into stepped mold 708 and stacked onto insulation film substrate 710 via connectors 720 (e.g., solder ball connectors). Processor die 702 may include at least one microprocessor, at least one “general-purpose” microprocessor, at least one special-purpose microprocessor, at least one ASIC, or some combination thereof. In some embodiments, processor die 702 may perform processing for specific functions, such as specific wireless communication related functions. Processor die 702 may be an embodiment of application processor 235.

Stepped mold 708 is a molded cavity that has portions of different heights (or thicknesses) along, e.g., z dimension. Stepped mold 708 may allow integration of components of system-in-package 700 of different thicknesses for reduction of an overall thickness of system-in-package 700. Stepped mold 708 may be further utilized for inclusion of at least one shielding layer into system-in-package 700. Additionally or alternatively, stepped mold 708 may be further utilized for inclusion of at least one thermal heat dissipating material into system-in-package 700. A thickness of stepped mold 708 may be, e.g., between 0.35 mm and 0.37 mm.

Insulation film substrate 710 may be connected to a multi-layer board 730 via connectors 724 (e.g., LGA connectors or BGA connectors). Insulation film substrate 710 may be an insulating build-up material. Alternatively, insulation film substrate 710 may be replaced with an interposer. Multi-layer board 730 may be external to system-in-package 700. Alternatively, multi-layer board 730 may be an integral part of system-in-package 700. Multi-layer board 730 may be replaced with a flexible board 730. Alternatively, multi-layer board 730 may be replaced with a board 730 having at least one embedded component. At least one additional passive element 718 (e.g., capacitor, inductor, resistor, etc.) may be directly stacked onto multi-layer board 730 via connectors 728 (e.g., LGA connectors or BGA connectors).

Each of first passive elements 704 and second passive element 706 may be at least partially integrated into stepped mold 708. First passive elements 704 and second passive element 706 may be capacitors, inductors, resistors, voltage regulators, some other type of passive elements, or some combination thereof. First passive elements 704 and second passive element 706 may be of different heights (or thicknesses). First passive elements 704 may be fully integrated into stepped mold 708 and directly stacked onto insulation film substrate 710. Second passive element 706 may be partially placed within a recess 732 of stepped mold 708 and partially placed through a cavity 722 (e.g., three-dimensional cavity) in insulation film substrate 710 for stacking second passive element 706 onto multi-layer board 730 via connectors 726 (e.g., LGA connectors or BGA connectors). A mechanical shield 734 may be placed around at least a portion of second passive element 706 (e.g., between stepped mold 708 and recess 732) to prevent overmold and to shield second passive element 706 that is stacked onto multi-layer board 730. By placing second passive element 706 partially within recess 732 of stepped mold 708 and partially through cavity 722 of insulation film substrate 710, an overall thickness of system-in-package 700 can be further reduced (e.g., in comparison with system-in-packages 300, 400, 500 and 600).

System-in-package 700 may further include a shielding layer 712 that covers stepped mold 708 as an outer layer of system-in-package 700. Shielding layer 712 may provide electrical shielding for components in system-in-package 700. A thickness of shielding layer 712 may be, e.g., between 7 μm and 15 μm. System-in-package 700 may further include an absorber layer 714 (e.g., EMI absorber) placed above at least a portion of an outer surface of shielding layer 712. Thus, absorber layer 714 may represent an outer layer of system-in-package 700. Alternatively or additionally, an absorber layer 716 (e.g., EMI absorber) may be placed below a portion of an inner surface of shielding layer 712. When a thickness of system-in-package 700 allows it (e.g., when the thickness of system-in-package 700 is below a specified maximum thickness), both absorber layers 714 and 716 may be employed for providing an increased level of electro-magnetic interference absorption. A maximum thickness of system-in-package 700 may be, e.g., 0.692 mm.

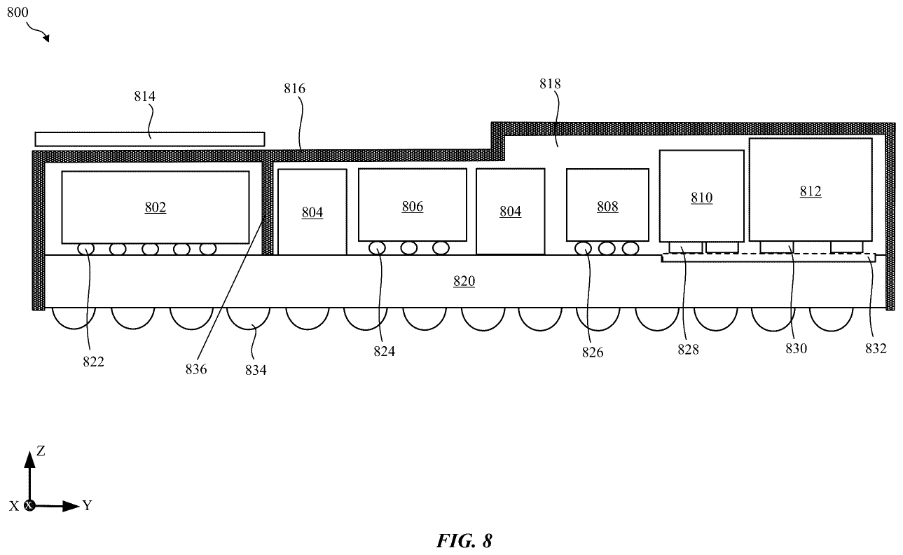

FIG. 8 is a schematic diagram of a system-in-package 800 that may be integrated into electronic device 100, according to one embodiment. System-in-package 800 may be a system-in-package integrated into front glass panel 232, main logic board 233, back glass panel 234, left side panel 236, or right side panel 238. System-in-package 800 may include at least one processor die 802, first passive elements 804, at least one radio frequency front-end die 806, at least one power control die 808, a second passive element 810, a third passive element 812, a stepped mold 818, and an insulation film substrate 820.

Processor die 802 may be integrated into stepped mold 818 and stacked onto insulation film substrate 820 via connectors 822 (e.g., solder ball connectors). Processor die 802 may include at least one microprocessor, at least one “general-purpose” microprocessor, at least one special-purpose microprocessor, at least one ASIC, or some combination thereof. In some embodiments, processor die 802 may perform processing for specific functions, such as specific wireless communication related functions. Processor die 802 may be an embodiment of application processor 235.

Stepped mold 818 is a molded cavity that has portions of different heights (or thicknesses) along, e.g., z dimension. Stepped mold 818 may allow integration of components of system-in-package 800 of different thicknesses for reduction of an overall thickness of system-in-package 800. Stepped mold 818 may be further utilized for inclusion of at least one shielding layer into system-in-package 800. Additionally or alternatively, stepped mold 818 may be further utilized for inclusion of at least one thermal heat dissipating material into system-in-package 800. A thickness of stepped mold 818 may be, e.g., between 0.57 mm and 0.59 mm. Insulation film substrate 820 may be connected to a multi-layer board (not shown in FIG. 8) via connectors 834 (e.g., LGA connectors or BGA connectors). Insulation film substrate 820 may be an insulating build-up material. Alternatively, insulation film substrate 820 may be replaced with an interposer.

Radio frequency front-end die 806 may provide a wireless communication functionality for system-in-package 800. Radio frequency front-end die 806 may be integrated into stepped mold 818 and stacked onto insulation film substrate 820 via connectors 824 (e.g., solder ball connectors). Radio frequency front-end die 806 may be an embodiment of transceiver 220. Power control die 808 may provide power control for, e.g., processor die 802 and/or radio frequency front-end die 806. Power control die 808 may be integrated into stepped mold 818 and stacked onto insulation film substrate 820 via connectors 824 (e.g., solder ball connectors). Power control die 808 may be an embodiment of power management circuit 239 and/or power management module 241.

Each of first passive elements 804, second passive element 810 and third passive element 812 may be integrated into stepped mold 818. In some embodiments, one or more of passive elements 804, 810 and 812 includes a voltage regulator. First passive elements 804, second passive element 810 and third passive element 812 may be capacitors, inductors, resistors, or some combination thereof. First passive elements 804, second passive element 810 and third passive element 812 may be of different heights (or thicknesses). First passive elements 804 may be directly stacked onto insulation film substrate 820. Second passive element 810 may be stacked onto insulation film substrate 820 via connectors 828 (e.g., LGA connectors). In one or more embodiments, connectors 828 are placed within a recess 832 of insulation film substrate 820. Third passive element 812 may be stacked onto insulation film substrate 820 via connectors 830 (e.g., LGA connectors). In one or more embodiments, connectors 830 may be placed within recess 832 of insulation film substrate 820. By integrating both second and third passive elements 810 and 812 into stepped mold 818 and by placing their associated connectors 828 and 830 within recess 832 of insulation film substrate 820, an overall thickness of system-in-package 800 can be further reduced (e.g., in comparison with system-in-packages 600 and 700).

System-in-package 800 may further include a shielding layer 816 that covers stepped mold 818 as an outer layer of system-in-package 800. Shielding layer 816 may provide electrical shielding for components in system-in-package 800. A thickness of shielding layer 816 may be, e.g., between 7 μm and 15 μm. System-in-package 800 may further include an absorber layer 814 (e.g., EMI absorber) placed above at least a portion of an outer surface of shielding layer 816. Alternatively, absorber layer 814 may be placed below a portion of an inner surface of shielding layer 816. Processor die 802 may be further shielded from radio frequency front-end die 806, power control die 808 and passive elements 804, 810, 812 by employing an extension 836 of shielding layer 816 placed within stepped mold 818. A maximum thickness of system-in-package 800 may be, e.g., 0.865 mm.

While particular embodiments and applications have been illustrated and described, it is to be understood that the invention is not limited to the precise construction and components disclosed herein and that various modifications, changes and variations which will be apparent to those skilled in the art may be made in the arrangement, operation and details of the method and apparatus disclosed herein without departing from the spirit and scope of the present disclosure.

What is claimed is:

1. A system-in-package comprising:
a stepped mold;
an insulation film substrate connected to a multi-layer board via a first plurality of connectors;
at least one processor die integrated into the stepped mold and stacked onto the insulation film substrate via a second plurality of connectors; and
at least one passive element integrated into the stepped mold and stacked onto the insulation film substrate.

2. The system-in-package of claim 1, wherein the at least one passive element comprises a plurality of passive elements of different heights integrated into the stepped mold.

3. The system-in-package of claim 1, wherein the at least one passive element is stacked onto the insulation film substrate via a plurality of land grid array (LGA) connectors that are placed within a recess of the insulation film substrate.

4. The system-in-package of claim 1, wherein a passive element of the at least one passive element is partially placed within a recess of the stepped mold and through a cavity of the insulation film substrate.

5. The system-in-package of claim 4, wherein the passive element is directly connected to the multi-layer board via a third plurality of connectors.

6. The system-in-package of claim 4, wherein a mechanical shield is placed around at least a portion of the passive element.

7. The system-in-package of claim 1, further comprising a shielding layer covering the stepped mold as an outer layer of the system-in-package.

8. The system-in-package of claim 7, further comprising an electro-magnetic interference (EMI) absorber placed above a portion of an outer surface of the shielding layer.

9. The system-in-package of claim 7, further comprising an electro-magnetic interference (EMI) absorber placed below a portion of an inner surface of the shielding layer.

10. The system-in-package of claim 1, wherein:
the first plurality of connectors comprise a plurality of land grid array (LGA) connectors or a plurality of ball grid array (BGA) connectors; and
the second plurality of connectors comprise a plurality of solder ball connectors.

11. The system-in-package of claim 1, wherein the insulation film substrate comprises an insulating build-up material.

12. The system-in-package of claim 1, further comprising at least one of a radio frequency front-end die and a power control die integrated into the stepped mold and stacked onto the insulation film substrate via a third plurality of connectors.

13. The system-in-package of claim 1, wherein the multi-layer board is external to the system-in-package.

14. A system-in-package comprising:
a stepped mold;
an insulation film substrate connected to a multi-layer board via a first plurality of connectors;
at least one processor die and at least one of a radio frequency front-end die and a power control die integrated into the stepped mold and stacked onto the insulation film substrate via a second plurality of connectors; and
a plurality of passive elements of different heights integrated into the stepped mold and stacked onto the insulation film substrate.

15. The system-in-package of claim 14, wherein the plurality of passive elements are stacked onto the insulation film substrate via a plurality of land grid array (LGA) connectors.

16. The system-in-package of claim 15, wherein the plurality of LGA connectors are placed within a recess of the insulation film substrate.

17. The system-in-package of claim 14, further comprising a shielding layer covering the stepped mold as an outer layer of the system-in-package.

18. The system-in-package of claim 17, wherein the at least one processor die is shielded from the at least one of the radio frequency front-end die and the power control die via an extension of the shielding layer placed within the stepped mold.

19. A system-in-package comprising:
a stepped mold;
a multi-layer board;
an insulation film substrate connected to the multi-layer board via a first plurality of connectors;
at least one processor die integrated into the stepped mold and stacked onto the insulation film substrate via a second plurality of connectors; and
a plurality of passive elements integrated into the stepped mold and stacked onto the insulation film substrate, one of the plurality of passive elements staked onto the insulation film substrate via a third plurality of connectors placed within a recess of the insulation film substrate.

20. The system-in-package of claim 19, further comprising at least one passive element directly connected to the multi-layer board via a fourth plurality of connectors.
